(19) United States
(12) Patent Application Publication
(10) Pub. No.: US 2025/0092337 A1
(43) Pub. Date: Mar. 20, 2025

(54) MASK CLEANING COMPOSITION, MASK CLEANING METHOD, AND METHOD OF MANUFACTURING DISPLAY APPARATUS

(71) Applicant: Samsung Display Co., Ltd., Yongin-si (KR)

(72) Inventors: Areum Lee, Yongin-si (KR); Hwi Kim, Yongin-si (KR); Jungsun Park, Yongin-si (KR); Jihee Son, Yongin-si (KR); Seoulki Lee, Yongin-si (KR); Seungjun Lee, Yongin-si (KR); Yeonhwa Lee, Yongin-si (KR); Joongu Lee, Yongin-si (KR)

(73) Assignee: Samsung Display Co., Ltd., Yongin-si (KR)

(21) Appl. No.: 18/675,410

(22) Filed: May 28, 2024

(30) Foreign Application Priority Data
Sep. 19, 2023 (KR) 10-2023-0124996

(51) Int. Cl. C11D 7/50

(52) U.S. Cl. CPC C11D 7/5013; C11D 2111/14; C11D 2111/44

(57) ABSTRACT

A mask cleaning composition for cleaning a deposition mask includes a solvent having a Hansen solubility parameter distance Rₐ₁ of 7.35 (MPa)^{1/2} or less, the Hansen solubility parameter distance Rₐ₁ being expressed by Equation below: Rₐ₁={4×(17.9−δD)²+(9.9−δP)²+(7.4−δH)²}^{1/2}, where δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

### CROSS-REFERENCE TO RELATED APPLICATION(S)

This application claims priority to and benefits of Korean Patent Application No. 10-2023-0124996 under 35 U.S.C. § 119, filed on Sep. 19, 2023, in the Korean Intellectual Property Office, the entire contents of which are incorporated herein by reference.

### BACKGROUND

### 1. Technical Field

One or more embodiments relate to a mask cleaning composition for cleaning a deposition mask, a mask cleaning method, and a method of manufacturing a display apparatus.

### 2. Description of the Related Art

Display apparatuses display an image based on display data. Display apparatuses provide images by using light-emitting diodes. Applications and structures of display apparatuses have diversified, and structures that are bent to have a selectable angle from a flat state are also being developed.

Display apparatuses may include pixels in a certain pattern in order to display an image. The pixels may include several layers including an emission layer. These layers may be arranged on a substrate in different patterns according to their types.

### SUMMARY

Embodiments provide a mask cleaning composition that ensures sufficient solubility of an organic substance remaining on a mask after a deposition process and has low surface tension, thereby remaining by a small amount on a surface of the mask.

Each layer of a display apparatus may be formed by spraying a deposition material toward a mask assembly having an opening corresponding to a pattern desired to be formed on a substrate. The mask assembly may be cleaned using a cleaning solution in order to remove a deposited material remaining on the mask assembly that does not pass through the opening. For example, the cleaning solution may remain on a surface of the mask assembly. The remaining cleaning solution may deteriorate a deposition quality, such as generation of gas during a subsequent deposition process using the mask assembly.

However, embodiments are not limited to those set forth herein. The above and other embodiments will become more apparent to one of ordinary skill in the art to which the disclosure pertains by referencing the detailed description of the disclosure given below.

According to one or more embodiments, a mask cleaning composition for cleaning a deposition mask may include a solvent having a Hansen solubility parameter distance Rₐ₁ of 7.35 (MPa)^{1/2} or less, the Hansen solubility parameter distance Rₐ₁ being expressed by Equation below.

$${R}_{a 1} = {\{ 4 \times {( 17.9 - δ D )}^{2} + {( 9.9 - δ P )}^{2} + {( 7.4 - δ H )}^{2} \}}^{1 / 2} \qquad [ Equation ]$$

In Equation, δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

A value of the δD of the solvent may be in a range of about 14.9 (MPa)^{1/2} to about 20.9 (MPa)^{1/2}, a value of the δP of the solvent may be in a range of about 6.9 (MPa)^{1/2} to about 12.9 (MPa)^{1/2}, and a value of the δH of the solvent may be in a range of about 4.4 (MPa)^{1/2} to about 10.4 (MPa)^{1/2}.

The solvent may have a surface tension of about 36 mN/m or less.

The mask cleaning composition may have a boiling point of about 176° C. or greater.

The solvent may include an amide-based compound, and the amide-based compound may include at least one selected from N,N-Diethylformamide, N,N-Dimethylpropionamide, N,N-Diethylacetamide, N-Butylacetamide, N,N-Dimethylisobutyramide, N-Ethyl Propanamide, and N-Methylbutanamide.

The solvent may include a non-reproductively toxic compound.

According to one or more embodiments, a mask cleaning method may include a first operation of cleaning a mask with a mask cleaning composition, wherein the mask cleaning composition may include a solvent having a Hansen solubility parameter distance Rₐ₁ of 7.35 (MPa)^{1/2} or less, the Hansen solubility parameter distance Rₐ₁ being expressed by Equation below.

$${R}_{a 1} = {\{ 4 \times {( 17.9 - δ D )}^{2} + {( 9.9 - δ P )}^{2} + {( 7.4 - δ H )}^{2} \}}^{1 / 2} \qquad [ Equation ]$$

In Equation, δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

A value of the δD of the solvent may be about 14.9 (MPa)^{1/2} to about 20.9 (MPa)^{1/2}, a value of the δP of the solvent may be about 6.9 (MPa)^{1/2} to about 12.9 (MPa)^{1/2}, and a value of the δH of the solvent may be about 4.4 (MPa)^{1/2} to about 10.4 (MPa)^{1/2}.

The solvent may have a surface tension of 36 mN/m or less.

The mask cleaning composition may have a boiling point of 176° C. or greater.

The solvent may include an amide-based compound, and the amide-based compound may include at least one selected from N,N-Diethylformamide, N,N-Dimethylpropionamide, N,N-Diethylacetamide, N-Butylacetamide, N,N-Dimethylisobutyramide, N-Ethyl Propanamide, and N-Methylbutanamide.

The first operation may be performed under a temperature in a range of about 40° C. to about 60° C.

The first operation may be performed by bringing the mask cleaning composition into contact with the mask by using a spray method or dipping method.

The mask cleaning method may further include at least one of a second operation of cleaning the mask by using ultrapure water, a third operation of cleaning the mask by using alcohol, and a fourth operation of drying the mask.

According to one or more embodiments, a method of manufacturing a display apparatus may include arranging a mask to face a substrate, aligning the mask and the substrate, supplying a deposition material from a deposition source facing the mask such that a deposition material is deposited on the substrate, and cleaning the mask using a mask cleaning composition, wherein the mask cleaning composition may include a solvent having a Hansen solubility parameter distance Rₐ₁ of 7.35 (MPa)^{1/2} or less, the Hansen solubility parameter distance Rₐ₁ being expressed by Equation below:

$${R}_{a 1} = {\{ 4 \times {( 17.9 - δ D )}^{2} + {( 9.9 - δ P )}^{2} + {( 7.4 - δ H )}^{2} \}}^{1 / 2} \qquad [ Equation ]$$

In Equation, δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

A value of the δD of the solvent may be in a range of about 14.9 (MPa)^{1/2} to about 20.9 (MPa)^{1/2}, a value of the δP of the solvent may be in a range of about 6.9 (MPa)^{1/2} to about 12.9 (MPa)^{1/2}, and a value of the δH of the solvent may be in a range of about 4.4 (MPa)^{1/2} to about 10.4 (MPa)^{1/2}.

The solvent may have a surface tension of about 36 mN/m or less.

The mask cleaning composition may have a boiling point of about 176° C. or greater.

The solvent may include an amide-based compound, and the amide-based compound may include at least one selected from N,N-Diethylformamide, N,N-Dimethylpropionamide, N,N-Diethylacetamide, N-Butylacetamide, N,N-Dimethylisobutyramide, N-Ethyl Propanamide, and N-Methylbutanamide.

The solvent may include a non-reproductively toxic compound.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view of a display apparatus according to an embodiment;

FIG. 2 is a schematic cross-sectional view taken along line II-II′ of FIG. 1;

FIG. 3 is a schematic cross-sectional view illustrating a method of manufacturing a display apparatus and a mask cleaning method, according to an embodiment;

FIG. 4 is a three-dimensional (3D) graph showing the distribution of solvents according to a Hansen solubility parameter and a Hansen solubility parameter sphere; and

FIGS. 5A, 5B, 5C, 5D, and 5E are graphs showing, over time, the luminance of a display apparatus manufactured using a mask cleaned with material X or a mask cleaning composition according to an embodiment.

### DETAILED DESCRIPTION

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

In case that a certain embodiment may be implemented differently, a specific process order may be performed differently from the described order. For example, two consecutively described processes may be performed substantially at the same time or performed in an order opposite to the described order.

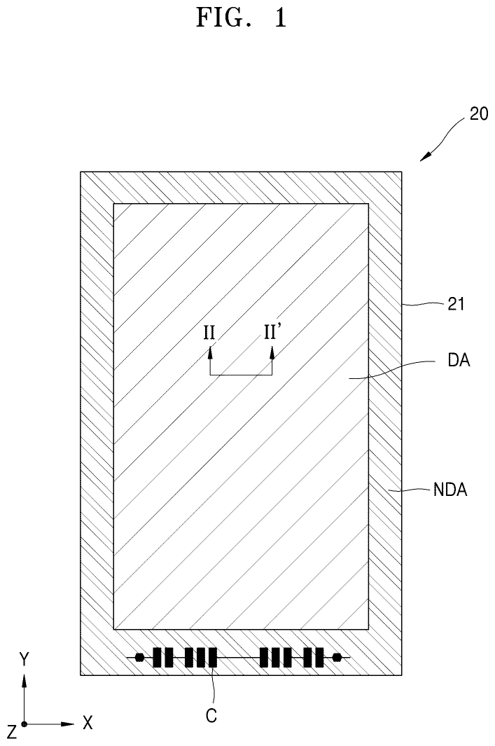

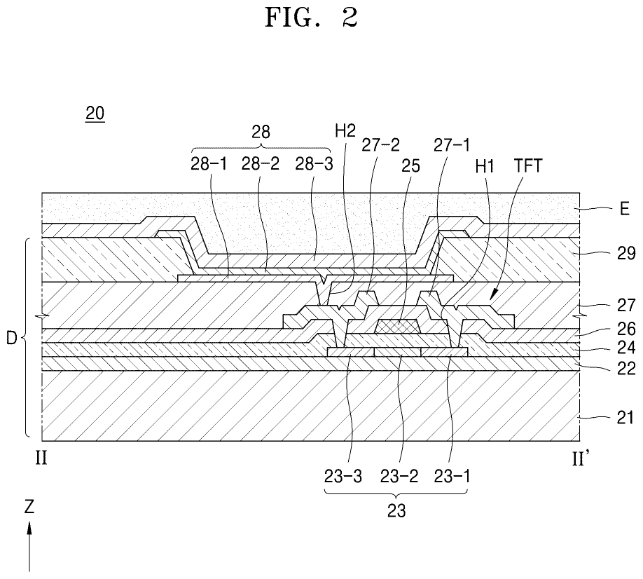

FIG. 1 is a schematic plan view of a display apparatus 20 according to an embodiment. FIG. 2 is a schematic cross-sectional view taken along line II-II′ of FIG. 1.

Referring to FIGS. 1 and 2, in the display apparatus 20, a display area DA and a non-display area NDA around the display area DA may be defined on a substrate 21.

An organic light-emitting device (OLED) 28 may be arranged in the display area DA. For example, a power wiring may be arranged in the non-display area NDA. A pad portion C may also be arranged in the non-display area NDA. In FIG. 1, the display area DA is illustrated as having a substantially rectangular shape. However, embodiments are not limited thereto, and the shape of the display area DA may be modified in various ways. Deposition material patterns may be arranged in the display area DA.

The display apparatus 20 may include a display substrate D, an intermediate layer 28-2 disposed on the display substrate D, and an opposite electrode 28-3 disposed on the intermediate layer 28-2. The display apparatus 20 may include a thin film encapsulation layer E formed on the opposite electrode 28-3.

The display substrate D may include the substrate 21, a thin film transistor TFT, a via layer 27, and a pixel electrode 28-1.

The substrate 21 may be formed of a plastic material, or may be formed of a metal material, such as, steel use stainless (SUS) or titanium (Ti). In another example, the substrate 21 may be formed of polyimide (PI).

The thin film transistor TFT may be formed on the substrate 21, the via layer 27 may be formed to cover the thin film transistor TFT, and the OLED 28 may be formed on the via layer 27.

A buffer layer 22, which is made of an organic compound and/or an inorganic compound, may be further formed on an upper surface of the substrate 21, and the buffer layer 22 may include silicon oxide (SiOₓ) or silicon nitride (SiNₓ).

An active layer 23, which is arranged in a certain pattern, may be formed on the buffer layer 22, and may be buried by a gate insulating layer 24. The active layer 23 may include a source region 23-1 and a drain region 23-3, and may further include a channel region 23-2 therebetween.

The active layer 23 may include various materials. For example, the active layer 23 may include an inorganic semiconductor material such as amorphous silicon or crystalline silicon. As another example, the active layer 23 may include an oxide semiconductor. As another example, the active layer 23 may include an organic semiconductor material.

The active layer 23 may be formed by forming an amorphous silicon layer on the buffer layer 22, by crystallizing the amorphous silicon layer to form a polycrystalline silicon layer, and by patterning the polycrystalline silicon layer. The source region 23-1 and the drain region 23-3 of the active layer 23 may be doped with impurities according to the types of the thin film transistors TFT, such as a driving transistor and a switching transistor.

A gate electrode 25 overlapping the active layer 23, and an interlayer insulating layer 26 which buries/covers the gate electrode 25 may be formed on an upper surface of the gate insulating layer 24. Contact holes H1 may be formed in (or pass through) the interlayer insulating layer 26 and the gate insulating layer 24, and a source electrode 27-1 and a drain electrode 27-2 may be formed on the interlayer insulating layer 26 such that the source electrode 27-1 and the drain electrode 27-3 may contact the source region 23-1 and the drain region 23-3, respectively, through the contact holes H1.

The via layer 27 may be formed on the thin film transistor TFT formed as described above, and the pixel electrode 28-1 of the OLED 28 may be formed on the via layer 27. The pixel electrode 28-1 may be in contact with the drain electrode 27-2 of the thin film transistor TFT through a via hole H2 formed in (or passing through) the via layer 27. The via layer 27 may be formed of an inorganic material and/or an organic material and formed as a single layer or multiple layers. The via layer 27 may be formed as a planarization layer such that an upper surface of the via layer 27 may be flat regardless of the unevenness of a lower layer under the via layer 27. In another example, the via layer 27 may be formed to be uneven according to the unevenness of the lower layer under the via layer 27.

After the pixel electrode 28-1 is formed on the via layer 27, a pixel defining layer 29 may be formed of an organic and/or inorganic material to cover the via layer 27 and a portion of the pixel electrode 28-1, and may be opened (or removed) to expose the pixel electrode 28-1.

The intermediate layer 28-2 and the opposite electrode 28-3 may be formed on the pixel electrode 28-1. According to an embodiment, the opposite electrode 28-3 may be formed on the entire surface of the display substrate D. For example, the opposite electrode 28-3 may be formed on the intermediate layer 28-2 and the pixel defining layer 29. The pixel electrode 28-1 may function as an anode, and the opposite electrode 28-3 may function as a cathode. In another example, the pixel electrode 28-1 may function as a cathode, and the opposite electrode 28-3 may function as an anode.

The intermediate layer 28-2 may include an organic emission layer. As another example, the intermediate layer 28-2 may include an organic emission layer, and may further include at least one of a hole injection layer (HIL), a hole transport layer (HTL), an electron transport layer (ETL), and an electron injection layer (EIL). Embodiments are not limited thereto, and the intermediate layer 28-2 may further include various other functional layers in addition to an organic emission layer.

The pixel electrode 28-1 and the opposite electrode 28-3 may be separated from each other by the intermediate layer 28-2, and respectively apply voltages of opposite polarities to the intermediate layer 28-2 so that light emission may be performed in the organic emission layer.

The intermediate layers 28-2 may include intermediate layers 28-2, and the intermediate layers 28-2 may form the display area DA. For example, the intermediate layers 28-2 may be spaced apart from each other and arranged in a certain pattern within the display area DA.

A unit pixel (e.g., single unit pixel) may include sub-pixels, and the sub-pixels may emit light of various colors. For example, the sub-pixels may include sub-pixels which respectively emit red light, green light, and blue light, or may include sub-pixels which respectively emit red light, green light, blue light, and white light. The sub-pixels may each include a single intermediate layer 28-2.

The thin-film encapsulation layer E may include inorganic layers, or may include an inorganic layer and an organic layer.

The organic layer of the thin-film encapsulation layer E may be formed of a polymer, and may be a single layer or a stacked layer formed of polyethylene terephthalate (PET), PI, polycarbonate (PC), epoxy, polyethylene, or polyacrylate.

The inorganic layer of the thin-film encapsulation layer E may be a single layer or a stacked layer including metal oxide or metal nitride. For example, the inorganic layer may include any one of SiNₓ, Al₂O₃, SiO₂, and TiO₂.

An uppermost layer exposed to the outside in the thin-film encapsulation layer E may be formed of an inorganic layer to prevent infiltration (or permeation) of moisture to the OLED 28.

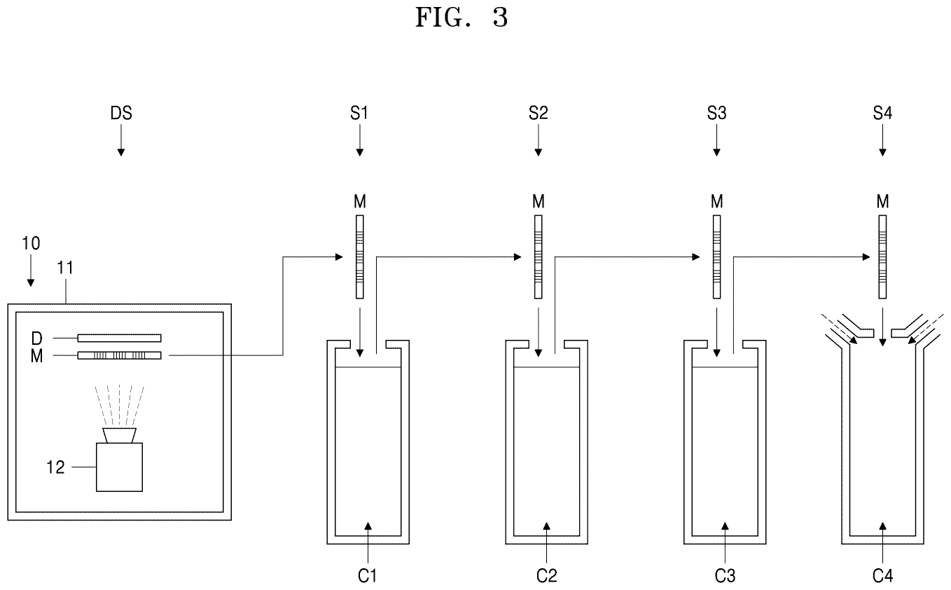

FIG. 3 is a schematic cross-sectional view illustrating a method of manufacturing a display apparatus and a mask cleaning method according to an embodiment.

Various layers of the display apparatus described above with reference to FIGS. 1 and 2 may be formed on a substrate through a deposition process. This deposition process may be performed by a manufacturing apparatus for the display apparatus, for example, a deposition apparatus 10.

The deposition apparatus 10 may include a chamber 11 that provides a space where a deposition process is performed, and a deposition source 12 that performs deposition by spraying a deposition material. The deposition apparatus 10 may further include various components such as a pressure control unit, a magnetic force unit, and a scanning unit, but these components are not illustrated in FIG. 3 for convenience of explanation.

To perform a deposition operation DS, a display substrate D, a mask M, and a deposition source 12 may be disposed in the chamber 11. For example, the display substrate D may be a processing target, and disposing a deposition material in a specific pattern on the display substrate D may be the deposition operation DS. Thus, the mask M may have openings in a shape corresponding to the specific pattern, and may be disposed between the display substrate D and the deposition source 12.

In case that the display substrate D, the mask M, and the deposition source 12 are disposed in the chamber 11, the deposition material may be sprayed from the deposition source 12 toward the display substrate D. For example, some of the deposition material sprayed from the deposition source 12 may pass through the openings formed in the mask M and may be disposed on the display substrate D. Accordingly, the deposition material may be disposed on the display substrate D in a pattern similar to the shape of the openings of the mask M.

According to an embodiment, the deposition source 12 may include a deposition material included in the intermediate layer 28-2 of FIG. 2, and the deposition material may be sprayed onto the display substrate D to form the intermediate layer 28-2 of FIG. 2. As the deposition material may be disposed on the display substrate D by passing through the openings formed in a certain pattern in the mask M, the intermediate layer 28-2 of FIG. 2 disposed on the display substrate D may be arranged in a similar pattern to the opening of the mask M.

After performing the deposition operation DS, a deposition material, which does not pass through the openings, may remain on at least one surface of the mask M. Thereafter, in order to repeatedly perform a separate deposition process, there is a need to remove the deposition material remaining on the mask M. For example, the mask M may be used repeatedly through a cleaning process.

An operation of cleaning the mask M may include a first operation S1 of cleaning the mask M using a first composition C1, a second operation S2 of cleaning the mask M using a second composition C2, a third operation S3 of cleaning the mask M using a third composition C3, and a fourth operation S4 of drying the mask M.

In the first operation S1, the mask M may be cleaned using the first composition C1. The first composition C1, which is a mask cleaning composition, may include a solvent capable of dissolving the deposition material remaining on the mask M. The mask cleaning composition may be a mixture of the solvent and distilled water in a certain ratio.

Thereafter, in the second operation S2, the mask M that has undergone the first operation S1 may be cleaned using the second composition C2. According to an embodiment, the second composition C2 may include deionized water or ultrapure water. According to another embodiment, the second composition C2 may include distilled water.

Thereafter, in the third operation S3, the mask M that has undergone the second operation S2 may be cleaned using the third composition C3. According to an embodiment, the third composition C3 may contain alcohol. According to some embodiments, the alcohol of the third composition C3 may include methanol, ethanol, pentanol, 2-methyl-2-butanol, 3-methyl-2-butanol, n-propanol, isopropanol, butanol, isobutyl alcohol, 2-butanol, 2-methyl-2-propanol, hexanol, cyclohexanol, benzyl alcohol, propyl alcohol, isopropyl alcohol, ethylene glycol, propylene glycol, diethylene glycol, glycerin, dipropylene glycol, or any combination thereof.

In the fourth operation S4, the mask M that has undergone the third operation S3 may be dried. Accordingly, the fourth composition C4 may be air. According to an embodiment, in the fourth operation S4, the liquid remaining on the surface of the mask M may be removed using an air knife to dry the mask M.

According to some embodiments, the first through fourth operations S1 through S4 may be performed in a temperature range of about 40 degrees (° C.) to about 60 degrees (° C.). According to some embodiments, at least one of the second through fourth operations S2 through S4 may be omitted.

In FIG. 3, the first through third operations S1 through S3 are illustrated as being performed using a dipping method. However, embodiments are not limited thereto. According to another embodiment, at least one of first through third operations may include a method of cleaning the mask M through various methods such as a spray method.

The first composition C1 used in the first operation S1 may be a mask cleaning composition, and may be required to ensure sufficient solubility for the deposition material remaining on the mask M. Accordingly, the first composition C1 may include a solvent for the deposition material.

In case that the first composition C1 remains on the surface of the mask M after the first operation S1, there is a risk of deteriorating a deposition quality in a separate deposition process using the mask M. Therefore, the first composition C1 may have a low surface tension so that the amount of the first composition C1 remaining on the mask surface may be reduced.

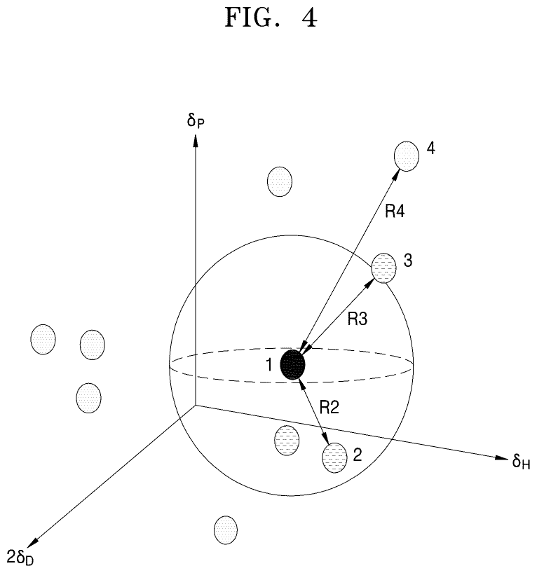

FIG. 4 is a three-dimensional (3D) graph showing the distribution of solvents according to a Hansen solubility parameter and a Hansen solubility parameter sphere.

Referring to FIG. 4, the Hansen solubility parameter may indicate the degree to which two substances positioned in a 3D space defined by axes defined by δ_{D}, δ_{H}, and δ_{P} are mixed with each other through a distance between the two substances. Two substances, which are close to each other in a 3D space, may be substances that are readily mixed with each other. Two substances, which are far apart from each other, may be substances that are difficult to mix with each other.

The axis δ_{D} may be the dispersion force axis of a material, the axis δ_{P} may be the polarity (or dipole energy) axis of the material, and the axis δ_{H} may be the hydrogen bonding axis of the material.

The deposited material is illustrated as a sphere marked 1. A cleaning composition for removing the deposition material 1 from the mask surface may be required to include a substance that is readily mixed with the deposition material 1, e.g., a substance (or solvent) in which the deposition material 1 readily dissolves. It may be understood that a substance has greater solubility of the deposition material 1 as the substance approaches the deposition material 1 in the 3D space illustrated in FIG. 4. A range in which a substance that is usable as a solvent of the deposition material 1 is distributed is illustrated as a sphere having a third distance R3 as a radius. For example, a third material 3 positioned the third distance R3 away from the deposition material 1 may be understood as one of substances providing a lowest solubility among the substances that are usable as a solvent for dissolving the deposition material 1. As a second material 2, which is separated from the deposition material 1 by a second distance R2, is positioned within the sphere, the second material 2 may be used as a solvent for dissolving the deposition material 1. As the second distance R2 is less than the third distance R3, the second material 2 may be suitable over the third material 3, as a solvent for the deposition material 1. As a fourth material 4, which is separated from the deposition material 1 by a fourth distance R4, is positioned outside the sphere, the fourth material 4 may not be used as a solvent for dissolving the deposition material 1.

The Hansen solubility parameter distance may be expressed by Equation 1 below.

$${R}_{a} = \sqrt{4 {( Δδ D )}^{2} + {( Δδ P )}^{2} + {( Δδ H )}^{2}} \qquad [ Equation 1 ]$$

where Rₐ may indicate the Hansen solubility parameter distance, and its unit may be (MPa)^{1/2}, δD may indicate the dispersion force term of a material, and its unit may be (MPa)^{1/2}, δP may indicate the polarity (or dipole energy) term of the material, and its unit may be (MPa)^{1/2}, and δH may indicate the hydrogen bonding term of the material, and its unit may be (MPa)^{1/2}. For example, the second distance R2 may be the Hansen solubility parameter distance determined by a difference in δD (or a dispersion force) between the deposition material 1 and the second material 2, a difference in δP (or polarity) between the deposition material 1 and the second material 2, and a difference in δH (or hydrogen bonding) between the deposition material 1 and the second material 2.

As a result, as the differences in δD, δP, and δH between two materials are reduced, the Hansen solubility parameter distance Rₐ, which is a distance between the two materials, in the 3D space illustrated in FIG. 4, may be reduced. Thus, the two materials may be readily mixed (or blended) with each other. Accordingly, it may be suitable to use a material as a solvent for another material.

In order to effectively remove the deposition material 1 remaining on the mask surface, the solubility of the cleaning composition with respect to the deposition material 1 may be sufficiently large. In order to effectively remove the deposition material 1 remaining on the mask surface, a Hansen solubility parameter distance between the deposition material 1 and the cleaning composition may be sufficiently small. For example, in order to reduce the amount of cleaning composition remaining on the mask surface, the surface tension of the cleaning composition may be low. This mask cleaning composition may be implemented by including a single material or multiple materials among the materials shown in Table 1 below. However, embodiments are not limited to the materials disclosed in Table 1 below.

TABLE 1

| | Surface tension | | | |
|---|---|---|---|---|
| Material name | (mN/m) | δD (MPa^{1/2}) | δP (MPa^{1/2}) | δH (MPa^{1/2}) |
| X | 40.1 | 17.9 | 9.9 | 7.4 |
| N,N-Diethylformamide | 27.8 | 16.7 | 11.1 | 7.7 |
| N,N-Dimethylpropionamide | 26.5 | 16.8 | 10.4 | 7.6 |
| N,N-Diethylacetamide | 27.3 | 16.7 | 9.5 | 5.4 |
| N-Butylacetamide | 27.9 | 17.0 | 11.0 | 8.8 |
| N,N-Dimethylisobutyramide | 26.1 | 16.6 | 9.1 | 6.4 |
| N-Ethyl Propanamide | 26.0 | 16.9 | 12.3 | 8.9 |
| N-Methylbutanamide | 26.0 | 17.1 | 12.0 | 8.9 |

Material X, which is a comparative example for the disclosure, may be N-methylpyrrolidone (NMP). According to an embodiment, a mask cleaning composition of which solubility with respect to the deposition material 1 is similar to that of the material X according to a comparative example may be implemented.

The Hansen solubility parameter distance between the material X and the mask cleaning composition may be expressed through Equation 2 below.

$${R}_{a} = \sqrt{4 {( 17.9 - δ D )}^{2} + {( 9.9 - δ P )}^{2} + {( 7.4 - δ H )}^{2}} \qquad [ Equation 2 ]$$

where Rₐ₁ may indicate the Hansen solubility parameter distance between the material X and the mask cleaning composition according to an embodiment, and its unit may be (MPa)^{1/2}.

In Equation 2, δD, δP, and δH may indicate the dispersion force term, polarity term, and hydrogen bonding force term of the mask cleaning composition, respectively, and have units of (MPa)^{1/2}.

In Equation 2, 17.9 may be the value of the dispersion power term of material X and may be expressed in a unit of (MPa)^{1/2}, 9.9 may be the value of the polarity term of material X and may be expressed in a unit of (MPa)^{1/2}, and 7.4 may be the value of the hydrogen bonding force term of material X and may be expressed in a unit of (MPa)^{1/2}.

A difference between the respective values of δD, δP, and δH of the mask cleaning composition and the respective values of δD (or 17.9 (MPa)^{1/2}), δP (or 9.9 (MPa)^{1/2}), and δH (or 7.4 (MPa)^{1/2}) of material X may be in a range of ±3.0 (MPa)^{1/2} or less.

For example, the δD value of the mask cleaning composition may be in a range of about 14.9 (MPa)^{1/2} to about 20.9 (MPa)^{1/2}. The δP value of the mask cleaning composition may be in a range of about 6.9 (MPa)^{1/2} to about 12.9 (MPa)^{1/2}. The δH value of the mask cleaning composition may be in a range of about 4.4 (MPa)^{1/2} to about 10.4 (MPa)^{1/2}.

Accordingly, the Hansen solubility parameter distance Rₐ₁ between the material X and the mask cleaning composition may be less than about √54≈7.384 (MPa)^{1/2}. Within the 3D space illustrated in FIG. 4, this mask cleaning composition may be close to material X and may be close to the deposition material 1, and the deposition material 1 may be cleaned using material X. Accordingly, the mask cleaning composition according to an embodiment may have a solubility (or cleaning power) similar to that of material X with respect to the deposition material 1.

The surface tension of the mask cleaning composition according to an embodiment may be less than the surface tension of material X. For example, the surface tension of the mask cleaning composition may be less than the surface tension of material X by 10% or more. According to an embodiment, the surface tension of the mask cleaning composition may be about 36.0 mN/m or less. Accordingly, this mask cleaning composition has a lower surface tension than material X, and thus may remain by a small amount on the mask after a cleaning step.

A boiling point of the mask cleaning composition according to an embodiment may be about 176 degrees (° C.) or more. Therefore, in a subsequent deposition process, the mask cleaning composition may not vaporize and thus not generate gas.

According to the Globally Harmonized System of Classification and Labeling of Chemicals (GHS) and the Material Safety Data Sheet (MSDS) of the Korea Safety and Health Agency following the GHS, material X (or N-methylpyrrolidone) may have reproductive toxicity (hazard statement H360). For example, the mask cleaning composition according to an embodiment may not include reproductive toxic compounds according to the GHS and MSDS classification. For example, the mask cleaning composition according to an embodiment may include only compounds that are non-reproductive toxic based on the GHS and MSDS classification. For example, all of the remaining substances except for material X among the materials listed in Table 1 may not have reproductive toxicity according to the GHS and MSDS classification.

As a result, according to an embodiment, a mask cleaning composition having a similar cleaning power with respect to a deposition material to material X, remaining on a mask by a smaller amount than material X due to a less surface tension than material X, and not including reproductive toxicity in contrast with material X may be provided.

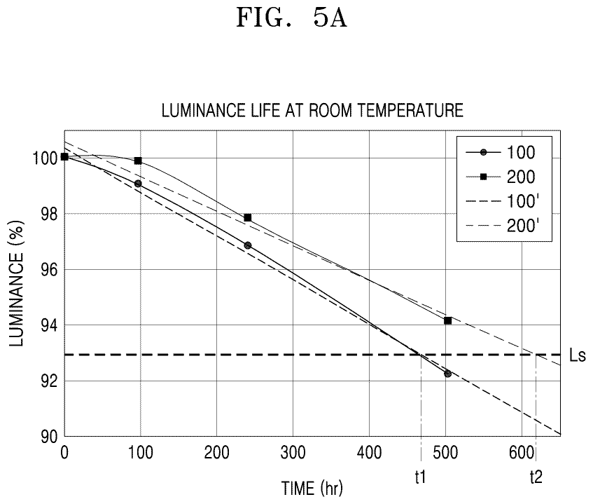

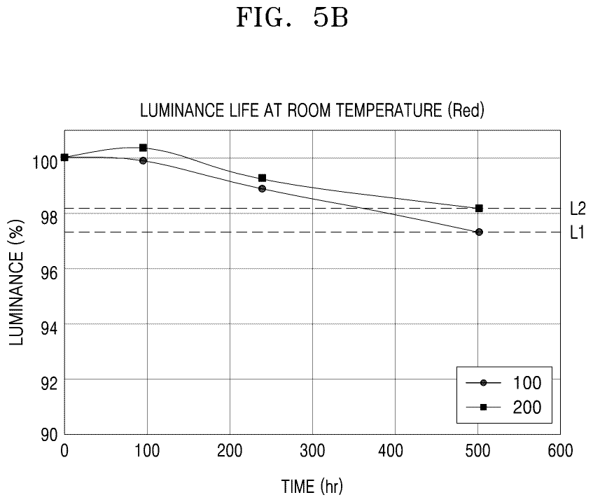

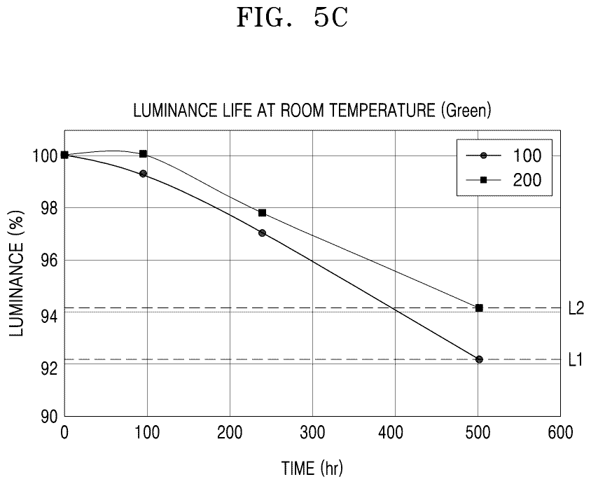

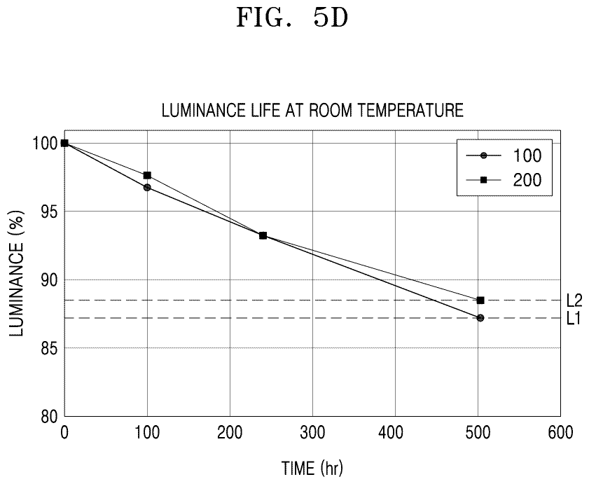

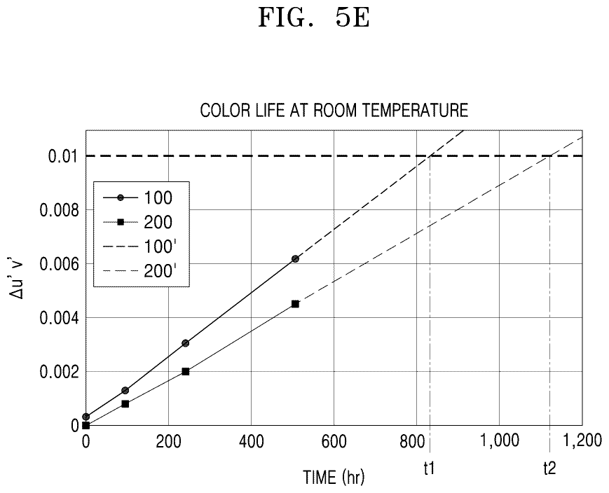

FIGS. 5A through 5E are graphs showing, over time, the luminance of a display apparatus manufactured using a mask cleaned with material X or a mask cleaning composition according to an embodiment.

FIGS. 5A through 5E show the luminance of the display apparatus over time in case that the display apparatus was operated to emit light with a luminance of about 500 nits at room temperature.

A first embodiment 100 illustrated in a solid line may be a comparative example for the disclosure, and shows the luminance of the display apparatus manufactured using the mask cleaned with material X. A second embodiment 200 illustrated in another solid line shows the luminance of the display apparatus manufactured using the mask cleaning composition according to an embodiment. A first trend 100′ illustrated in a dotted line overlapping the first embodiment 100 may be a trend line of the first embodiment 100. A second trend 200′ illustrated in a dotted line overlapping the second embodiment 200 may be a trend line of the second embodiment 200′.

In FIGS. 5A through 5D, a ‘luminance life’ refers to the time taken for the luminance of a pixel (or sub-pixel) of the display apparatus described above with reference to FIGS. 1 and 2, e.g., the luminance of the OLED 28 of FIG. 2, to decrease to a certain percentage of an initial luminance (e.g., approximately 500 nits). In the graphs, the x-axis may indicate time, and the unit may be hours. In the graphs, the y-axis may indicate luminance, which is expressed as a percentage (%) with respect to an initial lighting luminance (e.g., about 500 nits).

FIG. 5A shows a graph showing the luminance of a pixel of a display apparatus over time.

Referring to FIG. 5A, a reduction slope of the first embodiment 100 may be greater than that of the second embodiment 200. For example, the luminance of the first embodiment 100 may be about 92.3% after 500 hours, the luminance of the second embodiment 200 may be about 94% after 500 hours, and the luminance of the second embodiment 200 may be greater than that of the first embodiment 100.

Any luminance may be set as a threshold luminance Ls. According to an embodiment, the threshold luminance Ls may be about 93%. The time taken for the first embodiment 100 (or the first trend 100′) to reach the threshold luminance Ls may be defined as a first time t1. The first time t1 may be about 460 hours. The time taken for the second embodiment 200 (or the second trend 200′) to reach the threshold luminance Ls may be defined as a second time t2. The second time t2 may be about 613 hours.

FIG. 5B shows a graph showing the luminance of a red subpixel of a pixel of a display apparatus over time.

Referring to FIG. 5B, a reduction slope of the first embodiment 100 may be greater than that of the second embodiment 200. For example, a first luminance L1, which is the luminance of the first embodiment 100 after 500 hours, may be about 97.2%, and a second luminance L2, which is the luminance of the second embodiment 200 after 500 hours, may be about 98.2%. The second luminance L2 may be greater than the first luminance L1.

FIG. 5C shows a graph showing the luminance of a green subpixel of a pixel of the display apparatus over time.

Referring to FIG. 5C, a reduction slope of the first embodiment 100 may be greater than that of the second embodiment 200. For example, a first luminance L1, which is the luminance of the first embodiment 100 after 500 hours, may be about 92.3%, and a second luminance L2, which is the luminance of the second embodiment 200 after 500 hours, may be about 94.2%. The second luminance L2 may be greater than the first luminance L1.

FIG. 5D shows a graph showing the luminance of a blue subpixel of a pixel of the display apparatus over time.

Referring to FIG. 5D, a reduction slope of the first embodiment 100 may be greater than that of the second embodiment 200. For example, a first luminance L1, which is the luminance of the first embodiment 100 after 500 hours, may be about 87.2%, and a second luminance L2, which is the luminance of the second embodiment 200 after 500 hours, may be about 88.5%. The second luminance L2 may be greater than the first luminance L1.

As shown in FIGS. 5A through 5D, a luminance of the display apparatus according to the second embodiment 200 may be greater than that according to the first embodiment 100 in case that the same time period (e.g., 500 hours) was passed. For example, it may be considered that, in case that the same time period was passed, the luminance of the display apparatus manufactured using the mask cleaned with the mask cleaning composition according to an embodiment may be greater than the luminance of the display apparatus manufactured using the mask cleaned with material X.

As shown in FIG. 5A, the time period (or luminance life) taken to reach the same luminance (e.g., about 93%) in the second embodiment 200 may be longer than that in the first embodiment 100. For example, it may be considered that a luminance life of the display apparatus manufactured using the mask cleaned with the mask cleaning composition according to an embodiment may be longer than that of the display apparatus manufactured using the mask cleaned with material X.

FIG. 5E is a graph showing, over time, a distance by which light from the display apparatus is spaced apart from a location on a color coordinate system of initial light. In the graph of FIG. 5E, the x-axis may indicate time, and the unit may be hours. In the graph of FIG. 5E, the y-axis may indicate a separation distance Δu′v′ in a color coordinate system, which is an arbitrary value.

The color of light that a display apparatus's pixel emits under the same conditions may gradually change over time. The separation distance in the color coordinate system represents the degree to which the color of light is distant from another color, e.g., the degree of difference. In FIG. 5E, a ‘color life’ refers to the time taken for a location on the color coordinate system of the light emitted by the pixel (or subpixel) of the display apparatus to separate a certain distance from a location on the color coordinate system of initially-emitted light, e.g., the time taken for the color of light to change.

Referring to FIG. 5E, after 500 hours, the separation distance of the first embodiment 100 may be about 0.006, and the separation distance of the second embodiment 200 may be about 0.0045. Referring to FIG. 5D, the separation distance of the first embodiment 100 may be greater than the separation distance of the second embodiment 200.

Any separation distance may be set as a critical separation distance Ds. According to an embodiment, the critical separation distance Ds may be about 0.01. The time taken for the first trend 100′ to reach the critical separation distance Ds may be defined as a first time t1. The first time t1 may be about 832 hours. The time taken for the second trend 200′ to reach the critical separation distance Ds may be defined as a second time t2. The second time t2 may be about 1120 hours.

Therefore, in case that the same time (for example, 500 hours) was passed, the degree to which the color of light emitted by a pixel of the display apparatus differs from the color of initially-emitted light may be less in the second embodiment 200 than in the first embodiment 100. For example, it may be considered that, in case that the same time period was passed, the degree to which the color of light emitted by the display apparatus manufactured using the mask cleaned with the mask cleaning composition according to an embodiment may be less than the degree to which the color of light emitted by the display apparatus manufactured using the mask cleaned with material X.

For example, the time taken to reach the same separation distance (e.g., about 0.01) in the color coordinate system may be longer in the second embodiment 200 than in the first embodiment 100. For example, it may be considered that a color life of the display apparatus manufactured using the mask cleaned with the mask cleaning composition according to an embodiment may be longer than that of the display apparatus manufactured using the mask cleaned with material X.

According to an embodiment as described above, a mask cleaning composition may be implemented to maintain cleaning power against organic deposits remaining on a mask assembly and to have a low surface tension so that a small amount may remain on the surface of the mask assembly after cleaning. For example, a display apparatus with improved panel lifespan may be manufactured by implementing a mask cleaning method using such a mask cleaning composition and a display apparatus manufacturing method. The disclosure is not limited by this effect.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A mask cleaning composition for cleaning a deposition mask, the mask cleaning composition comprising:
a solvent having a Hansen solubility parameter distance Rₐ₁ of 7.35 (MPa)^{1/2} or less, the Hansen solubility parameter distance Rₐ₁ being expressed by Equation below:
$${R}_{a 1} = {\{ 4 \times {( 17.9 - δ D )}^{2} + {( 9.9 - δ P )}^{2} + {( 7.4 - δ H )}^{2} \}}^{1 / 2} \qquad [ Equation ]$$
where δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

2. The mask cleaning composition of claim 1, wherein
a value of the δD of the solvent is in a range of about 14.9 (MPa)^{1/2} to about 20.9 (MPa)^{1/2},
a value of the δP of the solvent is in a range of about 6.9 (MPa)^{1/2} to about 12.9 (MPa)^{1/2}, and
a value of the δH of the solvent is in a range of about 4.4 (MPa)^{1/2} to about 10.4 (MPa)^{1/2}.

3. The mask cleaning composition of claim 1, wherein the solvent has a surface tension of about 36 mN/m or less.

4. The mask cleaning composition of claim 1, wherein the mask cleaning composition has a boiling point of about 176° C. or greater.

5. The mask cleaning composition of claim 1, wherein
the solvent comprises an amide-based compound, and
the amide-based compound comprises at least one selected from N,N-Diethylformamide, N,N-Dimethylpropionamide, N,N-Diethylacetamide, N-Butylacetamide, N,N-Dimethylisobutyramide, N-Ethyl Propanamide, and N-Methylbutanamide.

6. The mask cleaning composition of claim 1, wherein the solvent comprises a non-reproductively toxic compound.

7. A mask cleaning method comprising:
a first operation of cleaning a mask using a mask cleaning composition,
wherein the mask cleaning composition comprises a solvent having a Hansen solubility parameter distance Rₐ₁ of 7.35 (MPa)^{1/2} or less, the Hansen solubility parameter distance Rₐ₁ being expressed by Equation below:
$${R}_{a 1} = {\{ 4 \times {( 17.9 - δ D )}^{2} + {( 9.9 - δ P )}^{2} + {( 7.4 - δ H )}^{2} \}}^{1 / 2} \qquad [ Equation ]$$
where δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

8. The mask cleaning method of claim 7, wherein
a value of the δD of the solvent is in a range of about 14.9 (MPa)^{1/2} to about 20.9 (MPa)^{1/2},
a value of the δP of the solvent is in a range of about 6.9(MPa)^{1/2} to about 12.9 (MPa)^{1/2}, and
a value of the δH of the solvent is in a range of about 4.4 (MPa)^{1/2} to about 10.4 (MPa)^{1/2}.

9. The mask cleaning method of claim 7, wherein the solvent has a surface tension of about 36 mN/m or less.

10. The mask cleaning method of claim 7, wherein the mask cleaning composition has a boiling point of about 176° C. or greater.

11. The mask cleaning method of claim 7, wherein
the solvent comprises an amide-based compound, and
the amide-based compound comprises at least one selected from N,N-Diethylformamide, N,N-Dimethylpropionamide, N,N-Diethylacetamide, N-Butylacetamide, N,N-Dimethylisobutyramide, N-Ethyl Propanamide, and N-Methylbutanamide.

12. The mask cleaning method of claim 7, wherein the first operation is performed under a temperature in a range of about 40° C. to about 60° C.

13. The mask cleaning method of claim 7, wherein the first operation is performed by bringing the mask cleaning composition into contact with the mask by using a spray method or dipping method.

14. The mask cleaning method of claim 7, further comprising at least one of:
a second operation of cleaning the mask by using ultrapure water;
a third operation of cleaning the mask by using alcohol; and
a fourth operation of drying the mask.

15. A method of manufacturing a display apparatus, the method comprising:
arranging a mask to face a substrate;
aligning the mask and the substrate;
supplying a deposition material from a deposition source facing the mask such that the deposition material is deposited on the substrate; and
cleaning the mask using a mask cleaning composition,
wherein the mask cleaning composition comprises a solvent having a Hansen solubility parameter distance Rₐ₁ of 7.35 (MPa)^{1/2} or less, the Hansen solubility parameter distance Rₐ₁ being expressed by Equation below:
$${R}_{a 1} = {\{ 4 \times {( 17.9 - δ D )}^{2} + {( 9.9 - δ P )}^{2} + {( 7.4 - δ H )}^{2} \}}^{1 / 2} \qquad [ Equation ]$$
where δD (MPa)^{1/2} indicates a dispersion power term of the solvent, δP (MPa)^{1/2} indicates a polarity term of the solvent, and δH (MPa)^{1/2} indicates a hydrogen bonding force term of the solvent.

16. The method of claim 15, wherein
a value of the δD of the solvent is in a range of about 14.9 (MPa)^{1/2} to about 20.9 (MPa)^{1/2},
a value of the δP of the solvent is in a range of about 6.9 (MPa)^{1/2} to about 12.9 (MPa)^{1/2}, and
a value of the δH of the solvent is in a range of about 4.4 (MPa)^{1/2} to about 10.4 (MPa)^{1/2}.

17. The method of claim 15, wherein the solvent has a surface tension of about 36 mN/m or less.

18. The method of claim 15, wherein the mask cleaning composition has a boiling point of about 176° C. or greater.

19. The method of claim 15, wherein
the solvent comprises an amide-based compound, and
the amide-based compound comprises at least one selected from N,N-Diethylformamide, N,N-Dimethylpropionamide, N,N-Diethylacetamide, N-Butylacetamide, N,N-Dimethylisobutyramide, N-Ethyl Propanamide, and N-Methylbutanamide.

20. The method of claim 15, wherein the solvent comprises a non-reproductively toxic compound.
